(19) United States
(12) Patent Application Publication
(10) Pub. No.: US 2005/0050427 A1
(43) Pub. Date: Mar. 3, 2005

(54) Method of rate matching for link adaptation and code space management

(76) Inventors: Gibong Jeong, San Diego, CA (US); Yan Hui, San Diego, CA (US); Douglas J. McPherson, San Diego, CA (US)

Correspondence Address: TEXAS INSTRUMENTS INCORPORATED, P O BOX 655474, M/S 3999, DALLAS, TX, 75265, US

(21) Appl. No.: 10/652,673

(22) Filed: Aug. 29, 2003

(51) Int. Cl. H03M 13/00

(52) U.S. Cl. 714/755

(57) ABSTRACT

A method of symbol combining and incremental redundancy for link adaptation and code space management was proposed. In order to reduce constraints on the Walsh codes allocation, MCS level change, as well as frame duration change for the initial transmission and re-transmissions, a “rate matching” stage is proposed between the Turbo encoder and block interleaver on the transmitter. In the initial transmission, the Turbo encoded symbols are interleaved with or without any puncturing or repeating (i.e. puncture/repeat factor is set to 1). The coded symbols are also stored in the memory for possible retransmissions. In the re-transmission, the transmitter first determines the number of Walsh codes available for this user and MCS level and frame duration according to the C/I feedback values from MS. The stored coded symbols are then punctured or repeated according to “rate matching factors”. On the receiver side, “rate matching factors” can be derived from the number of code channels, MCS level and frame duration of current re-transmissions and initial transmission. Then, de-puncturing/de-repeating is performed before coded symbol combining. A similar rate matching based IR/symbol combining scheme can be used to design different IR using different rate matching algorithms. It has low implementation complexity and is easily made backward compatible.

### BACKGROUND OF THE INVENTION

1. Field of the Invention

This invention relates generally to wireless data communications, and more specifically to a method of rate matching for link adaptation and code space management.

2. Description of the Prior Art

In high-speed data standards currently under development in 3GPP and 3GPP2, hybrid automatic retransmission request (H-ARQ) has been shown to have the capability to improve system throughput. Chase combining has been used together with ARQ to achieve higher throughput on the forward link by exploring time diversity. In this scheme, the re-transmission data are simply the same set of the initial transmission; and the receiver performs soft symbol (modulated soft symbol or channel coded soft symbol) combining. This is a simple, yet efficient form of Hybrid ARQ (H-ARQ). It has been shown that Chase combining provides similar performance compared to incremental redundancy (IR) under certain channels conditions, with less complexity and less memory requirement.

In 3GPP's HSDPA, incremental redundancy (IR) and symbol combining have been adopted together with ARQ to achieve higher throughput on the forward link via link adaptation. In one proposed framework, IR has also been adopted with symbol combining as a subset of it. In these H-ARQ schemes, the transmitted and re-transmitted data are either a subset of the encoded packet (IR) or simply the same set of the encoded packet (symbol combining). The receiver performs soft symbol combining accordingly. It can be seen that symbol combining is a subset of IR. In fact, when all the sub-packets have been transmitted in the re-transmissions in a full IR, symbol combining is used for the sequential re-transmission because the same set of sub-packets will be re-transmitted.

It is desirable for an IR method to enable link adaptation without significant increase in the implementation complexity and extra signaling, and with backward compatibility. Link adaptation is achieved through changing of channel code rate and modulation order. Walsh space change, i.e. availability of number of Walsh channels, due to the resource management by a base station should also be handled properly and easily by an IR method. It is further desirable for a single method to handle IR, full and partial symbol combining.

Despite the advantages described herein above, Chase combining as suggested by others has the following two obvious disadvantages:
1) If the Walsh space available for the data channel reduces between transmissions of a frame in a particular H-ARQ channel to the next transmission, the base station (BTS) cannot perform the re-transmission because it requires the same number of modulated symbols for each (re)transmission. As a result, the transmitter has to abort that particular frame; and
2) It requires each re-transmission to use the same modulation and coding scheme (MCS) as the original transmission, even when the channel changes from the initial transmission condition. Therefore, it introduces certain inefficiency on link adaptation, especially with higher numbers of ARQ channels.

Partial Chase combining has been proposed by other to address problem 1) above. A convenient way to implement partial Chase combining is to make the Walsh codes used for re-transmission always a subset of the original transmission. The advantage is that partial combining can be done by simply aligning the Walsh index for re-transmission with the original Walsh index. No extra information is required from the BTS. This technique however, imposes a significant constraint on the scheduling of other users (in a CDM system) and re-transmission of this user, which makes H-ARQ less efficient. A partial Chase combining capable of using a different modulation level has also been proposed by others. This technique is much less complex compared to full incremental redundancy (IR), yet solves the problem of limited Walsh space in re-transmissions. This technique proposed re-transmission of part of the original coded bits in a sequential manner (possibly with different modulation order). If the receiver fails to decode a control channel during one of the re-transmissions, there would be ambiguity on Walsh channel alignment between the transmitter and the receiver.

It is necessary to adaptively change MCS level in order to address problem 2) described herein above. One such solution is IR. A full IR provides the flexibility of changing coding rate by using different puncture patterns in a Turbo encoder. The memory requirement is large for full IR however, compared to Chase combining because it usually has to support a very low code rate. Further, the implementation complexity may be high due to different puncture patterns that must be supported in the Turbo encoder/decoder.

In CDMA2000 Release C, i.e. so-called 1xEV-DV standard,, a so-called adaptive asynchronized IR (AAIR) is adopted for the forward link. In this method, a so-called quasi complementary turbo code (QCTC) scheme is used to format the sub-packets for the transmissions. It provides the flexibility of changing coding rate by using different puncture patterns on the turbo encoded packets. The puncture pattern is defined by a set of matrices. Variable frame length can also be used to achieve more adaptation. The implementation complexity is high for this method, especially on the mobile station side, because it requires a complicated puncture pattern calculation and memory management. The complexity introduced to the mobile station by this method makes it unsuitable on the reverse link.

In 3GPP, IR is adopted as a general H-ARQ method for HSDPA. However, it has reported recently that at higher code rates there is a rather large degradation relative to the expected performance for several code rates. It was reported to be related to the rate-matching algorithm. This may be resulted from the fact the algorithm does not have “regular” puncturing pattern, which in turns results in puncturing out some parity bits in a non-regular fashion.

In view of the foregoing, it would be both advantageous and desirable in the data communication art to provide a method of symbol combining for link adaptation and code space management that overcomes the disadvantages described herein above. It would be further advantageous and desirable to provide an IR scheme for link adaptation and code space management that is more generic than known IR schemes.

### SUMMARY OF THE INVENTION

The present invention is directed to a method of symbol combining for link adaptation and code space management. In order to reduce constraints on the Walsh codes allocated for the initial transmission and re-transmissions, a “rate matching” stage is implemented between the Turbo encoder and block interleaver on the forward link transmitter. In the initial transmission, the Turbo encoded symbols are interleaved without any puncturing or repeating (i.e. puncture/repeat factor is set to 1). The coded symbols are also stored in the memory for possible retransmissions. In the re-transmission, the BTS first determines the number of Walsh codes available for this user and MCS level according to the C/I feedback values from MS. The stored coded symbols are then punctured or repeated according to “rate matching factors”, as defined herein below.

On the receiver side, “rate matching factors” can be derived from the number of code channels and MCS level of current re-transmissions and initial transmission. Then, de-puncturing/de-repeating is performed before coded symbol combining (partial Chase combining).

The present invention is also directed to a method of incremental redundancy for link adaptation and code space management. Incremental redundancy is achieved through sending different sub-packets via the “rate matching” stage discussed herein before. In the initial transmission, the turbo encoder encodes the entire input bits into encoded symbols without any puncturing (or with certain turbo puncturing between the encoder and H-ARQ memory blocks to obtain the lowest code rate required by IR). The encoded packet (EP) is stored in the memory for possible re-transmissions. After it determines modulation and code scheme (MCS) according to the C/I values feedback from the mobile station (MS), and number of Walsh channel and the radio frame length according to the resource management algorithm, the transmitter chooses an appropriate rate matching parameter set for this initial transmission, and uses it to generate a sub-packet (SP) from the EP for this transmission. If re-transmission is required due to the unsuccessful decoding of the received SP, as indicated by the acknowledge channel from the receiver, the transmitter chooses another appropriate rate matching parameter set according to the given MCS, number of Walsh codes, and radio frame length, and then uses it to obtain a SP from the original EP in the H-ARQ memory.

On the receiver side, the rate matching parameter set can be derived from the number of code channels, MCS level, and parameter(s) known to both sides, such as radio frame index or scrambling code. This is applied to both initial transmissions and re-transmissions. The, de-puncturing/de-repeating is performed before coded symbol combining, including IR combining, and full or partial symbol combining. The foregoing process is repeated until either a packet is successfully decoded or the maximum number of transmissions is reached.

According to one embodiment, a method of link adaptation and code space management comprises the steps of encoding original transmission bits into initial turbo encoded symbols; storing the initial turbo encoded symbols; interleaving and transmitting the initial turbo encoded symbols; determining the number of Walsh codes available for a desired user and a modulation and coding scheme (MCS) level according to carrier to interference (C/I) feedback values from a desired mobile station; determining rate matching factors corresponding to the number of available Walsh codes and the MCS level; selectively puncturing or repeating the stored turbo encoded symbols based on the rate matching factors; and re-transmitting the turbo encoded symbols subsequent to selectively puncturing or repeating the turbo encoded symbols.

According to another embodiment, a method of link adaptation and code space management comprises the steps of selectively turbo puncturing or avoiding puncturing of original transmission bits to generate an encoded packet (EP) having the lowest code rate required by a desired incremental redundancy (IR); storing the EP in a hybrid automatic re-transmission request (H-ARQ) memory; determining the number of Walsh codes available for a desired user, a modulation and coding scheme (MCS) level according to carrier to interference (C/I) feedback values from a desired mobile station, and the radio frame length according to a resource management algorithm; determining rate matching factors corresponding to the number of available Walsh codes, the MCS level, and the radio frame length; generating a sub-packet (SP) from the EP based on the rate matching factors; and transmitting the SP.

According to yet another embodiment, a link adaptation and code space management system comprises a transmission system comprising a channel encoder; a hybrid automatic re-transmission request (H-ARQ) memory operational to store symbols generated via the channel encoder; a rate matching stage operational to generate rate matching parameters corresponding to the number of available Walsh codes, modulation and code scheme (MCS) level according to carrier to interference feedback values from a mobile receiver, and radio frame length according to a resource management algorithm; and a receiving system comprising a rate matching stage operational to re-generate the rate matching parameters; a coded symbol combiner stage operational to implement at least one coded symbol combining of the type selected from the group consisting of incremental redundancy combining, full symbol combining, and partial symbol combining; and a channel decoder operational to decode the coded symbols generated via the coded symbol combiner stage.

### BRIEF DESCRIPTION OF THE DRAWINGS

Other aspects and features of the present invention and many of the attendant advantages of the present invention will be readily appreciated as the aspects and features become better understood by reference to the following detailed description when considered in connection with the accompanying drawings in which like reference numerals designate like parts throughout the figures thereof and wherein:

FIG. 1 is a block diagram illustrating a flexible modulation and coding scheme (MCS) associated with partial Chase combining and/or incremental redundancy; and

FIG. 2 is a block diagram illustrating an example of applying the proposed method to a forward shared channel structure.

While the above-identified drawing figures set forth alternative embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION OF THE PREFERRED EMBODIMENTS

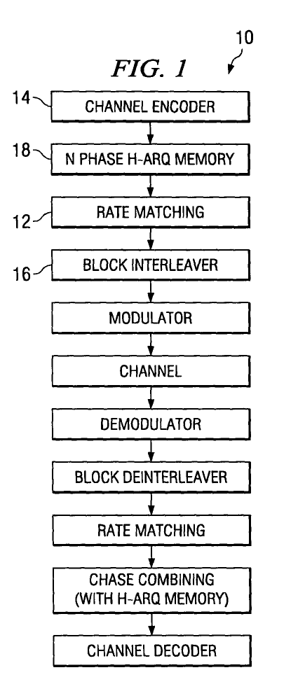

FIG. 1 is a block diagram illustrating a flexible modulation and coding scheme (MCS) 10 associated with partial Chase combining and/or incremental redundancy (IR). To reduce constraints on the data format for the initial transmission and retransmissions, such as MCS, number of Walsh codes, frame duration etc., a “rate matching” block 12 is implemented between the Turbo encoder 14 and block interleaver 16 on the forward link transmitter. In the initial transmission, the Turbo encoded symbols are block interleaved without any puncturing or repeating (i.e. puncture/repeat factor is set to 1). Note that there can be puncturing before the block interleaver on the Turbo encoded data. The coded symbols are also stored in the memory 18 for possible re-transmissions. In the re-transmission, the BTS first determines the number of Walsh codes available for this user and MCS level according to the C/I feedback values from the MS. Then the stored coded symbols are punctured or repeated according to “rate matching factors” (defined herein below). On the receiver side, the “rate matching factor” can be derived from the number of code channels and MCS level of current re-transmissions and initial transmission. Then, de-puncturing/de-repeating is performed before coded symbol combining (partial Chase combining).

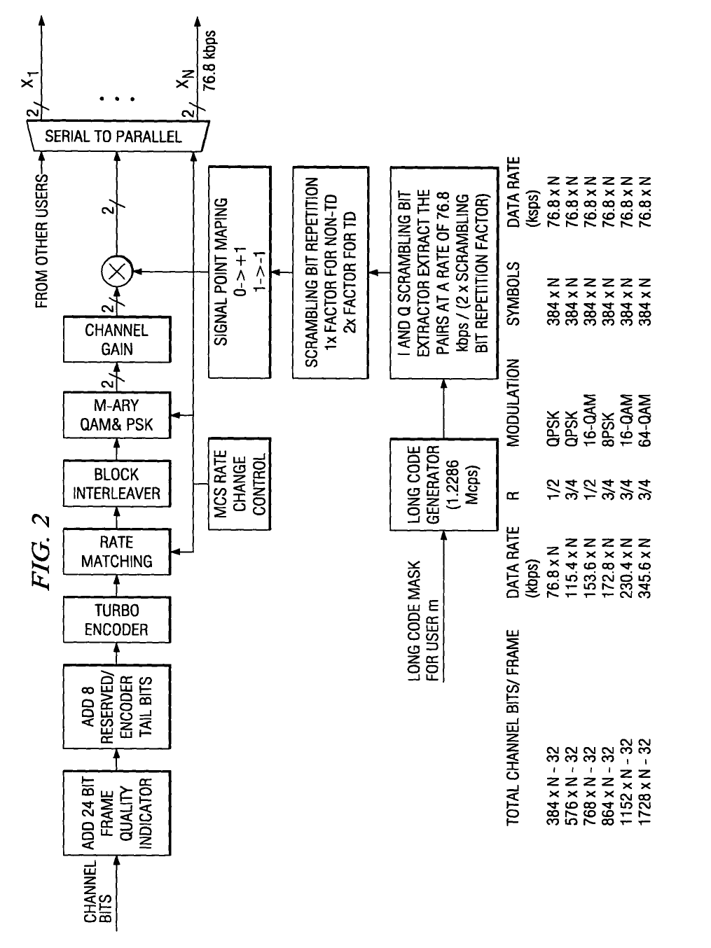

“Rate matching factors”, i.e. puncturing factor or repetition factor, can be determined as follows. Assume the initial transmission uses K₀ Walsh channels and the modulation order is M₀, and a re-transmission uses K₁ Walsh channels and the modulation order is M₁. The number of encoded symbols per frame at encoder 14 output is L=N_symbols*log₂M₀*K₀, and the block interleaver 16 size for this re-transmission is N=N_symbols*log₂M₁*K₁, where N_symbols is the number of modulation symbols and it is 384 in this example of FIG. 2. To re-transmit the same frame, L remains the same while N varies according to the resource and channel conditions (available Walsh code, and modulation order for a given C/I).

“Rate matching” in the transmitter shall be operated as follows.
1) Puncturing

The k^{th} output symbol from the puncturing block shall be the [kL/N]th input symbol, where
K=0 to N−1;
L=Number of encoded symbols per frame at encoder output; and
N=Desired block interleaver size (N<L).
2) Repetition

The k^{th} output symbol from the puncturing block shall be the [kL/N]th input symbol, where
k=0 to N−1;
L=Number of encoded symbols per frame at encoder output; and
N=Desired block interleaver size (N>L).

The receiver performs the same operation in order to de-puncture and de-repeat the received symbols. The present inventors found that this method can be made robust to the errors in the control channels by implementing a log₂M-bit field (where M is the highest modulation order) to indicate modulation level (log₂M₀) of the original transmission; and by implementing a [Log₂K₀]-bit field to indicate the number of code channels (K₀) of the original transmission.

FIG. 2 is a block diagram illustrating an example of the forward shared channel structure associated with the partial Chase combining technique depicted in FIG. 1. The present inventors found this forward shared channel structure advantageous since 1) it has no constraints on the Walsh space for re-transmission; 2) it supports any combination of modulation order and the number of available Walsh codes; 3) each re-transmitted data is self-decodable; and 4) the “Rate matching” algorithm can be made backward compatible to the rate matching method of the existing standards, such as IS-2000 Release A.

A Special Case

By making the “rate matching factor” equal to 1, i.e. no puncturing or repetition, the present inventors derived a special case as follows.

Walsh codes for the re-transmission are not necessarily a subset of the Walsh codes previously used; as a result, the base code for the partial re-transmission is not necessarily aligned with certain Walsh code index in the previous transmission. In order to make partial Chase combining work, the starting point for the partial combining must be given by BTS. Two methods for identifying the starting point of the partial packets were implemented by the present inventors as follows.

Method 1

Use a [Log₂K]-bit field in control channel to indicate one of the K possible starting points for partial combining, where K is number of Walsh code. The advantage of this method is that the BTS has the flexibility to re-transmit the partial packets in any order without any ambiguity.

Method 2

Use 2 bits ACK/NACK on reverse acknowledge channel. One bit is for data traffic channel ACK/NACK, and one bit is for control channel ACK/NACK. One ACK bit for control channel is to indicate whether a control channel has been successfully decoded. If the control channel is successfully decoded while the data traffic channel is not, the BTS will transmit next partial packet; if the control channel is not successfully decoded, the BTS will re-transmit the current partial packet. The partial packets are transmitted in a sequential order. Due to inherent flexibility, the BTS will not however, be able to re-transmit the partial packets in any order.

The present inventors found this special case to provide advantages including 1) no constraints on the Walsh space for re-transmission; and 2) it still uses simple soft symbol combining with no added complexity and no changes on F-SHCH.

In summary explanation of the foregoing, a method applies a “rate matching” like algorithm to Chase combining to make re-transmission data rate more flexible. It is capable of generating the number of coded symbols required by any combination of modulation order and the number of available Walsh codes, which makes the associated scheduling algorithm less constrained and link adaptation more efficient. Each re-transmitted data is self-decodable. A special case of this method simply makes the MCS of each re-transmission the same as the initial transmission while using available code space to transmit part, all, or (partly or entirely) repetition of the original transmission. Two signaling methods were described to implement this special case.

Looking again at FIG. 1, a “rate matching” block 12 is implemented between the Turbo encoder 14 and block interleaver 16 on the transmitter side as stated herein before. Rate matching block 12 was implemented by the present inventors to also achieve incremental redundancy (IR) through sending different sub-packets as now described herein below.

In the initial transmission, the Turbo encoder encodes the entire input bits into encoded symbols without any puncturing (or with certain turbo puncturing between the encoder 14 and H-ARQ memory blocks 18 to obtain the lowest code rate required by IR). The encoded packet (EP) is stored in the memory 18 for possible retransmissions. After it determines the modulation and code scheme (MCS) according to the C/I feedback values from the mobile, and number of Walsh channels and the radio frame length according to the resource management algorithm, the transmitter chooses an appropriate rate matching parameter set for this initial transmission, and uses it to generate a sub-packet (SP) from the EP for this transmission. If re-transmission is required due to the unsuccessful decoding of the received SP, as indicated by the acknowledge channel from the receiver, the transmitter chooses another appropriate rate matching parameter set according to the given MCS, number of Walsh codes, and radio frame length, then uses it to obtain a SP from the original EP in the H-ARQ memory 18.

On the receiver side, the rate matching parameter set can be derived from the number of code channels, MCS level, and parameter(s) known to both sides, such as radio frame index or scrambling code. This is applied to both initial transmissions and re-transmissions. Then, de-puncturing/de-repeating is performed before coded symbol combining, including IR combining, and full or partial symbol combining. This process is repeated until either a packet is successfully decoded or the maximum number of transmissions is reached.

A variety of rate matching algorithms can be used in this method, such as those disclosed in IS-2000 Release A Addendum, 3GPP Release 99, and so on. However, certain modifications may be needed when using such known rate matching algorithms to make this method work for IR, partial symbol combining (where different rate matching parameter sets are used for re-transmissions), and full symbol combining, i.e. Chase combining (where same rate matching parameter sets are used for re-transmissions). One such rate matching algorithm and the method to choose the parameter set for different IR is described herein below.

### Rate Matching Algorithm and Parameter Selection

The rate matching (RM) algorithm and parameters shall be determined according to different objectives, i.e. IR, full symbol combining, or partial symbol combining. The following RM algorithm, which includes RM of IS-2000 release A as a special case, is used to illustrate how to use the RM algorithm to implement a method to achieve a different IR as well its flexibility.

Assume the encoder packet (EP) size is L coded symbols, the maximum number of transmissions is I, the number of modulated symbols in one radio frame is J₁, the i-th (re)transmission uses Kᵢ Walsh channels and the modulation order is Mᵢ where i=0, 1, . . . I−1. Then, the sub-packet (SP) size for the i-th transmission of a particular EP is Nᵢ=Jᵢ(log₂ Mᵢ)Kᵢ. Note that the variable radio frame length is supported through varying Jᵢ. To perform re-transmission of the SP from the same EP, L remains the same while Nᵢ varies according to the resource (available Walsh code Kᵢ) and channel conditions (modulation order Mi for a given C/I).

To perform generalized IR, the “rate matching” in the transmitter is operated as follows:
1) Puncturing

In order to transmit a different portion of the original symbols in the puncturing case even when Nᵢ remains the same for each transmission, factors Dᵢ or Sᵢ, or both are introduced. Dᵢ is an integer between 0 and L−Nᵢ and Sᵢ is an integer between 0 and L−[(Nᵢ−1)L/Nᵢ]. Clearly, Sᵢ defines a symbol offset between the beginning of an EP and that of a SP, while Dᵢ helps define the frequency at which symbols are punctured. In order to obtain “uneven” puncturing output, Dᵢ can be chosen properly, or more than one Dᵢ and/or Sᵢ value can be use in one (re)transmission.

The k-th output symbol from the rate matching block (i.e. the k-th SP symbol) shall be the ([kL/(Nᵢ+Dᵢ)]+Sᵢ)-th input symbol (i.e. the EP symbol), where k=0 to Nᵢ−1.
2) Repetition

A similar offset can be defined for the repetition case. However, it does not provide as significant of an advantage as in the puncturing case.

The k-th output symbol from the rate matching block (i.e. the k-th SP symbol) shall be the [kL/Nᵢ]-th input symbol (i.e. the EP symbol), where k=0 to Nᵢ−1.

The receiver performs the same operation in order to de-puncture and de-repeat the received symbols.

Different IR schemes can be realized by properly choosing one or both offsets for each transmission.
1. Full symbol combining (Chase combining):

In this case, rate matching is not performed, i.e. L=Nᵢ, Dᵢ=0, Sᵢ=0, for i=0, . . . , l−1.
2. Partial symbol combining:

In the initial transmission, SP size is equal to EP size, i.e. N₀=L. Nᵢ can be equal, smaller, or larger than L in the re-transmissions. Dᵢ=Sᵢ=0, for i=0, and Dᵢ and Sᵢ for i>0 can be properly chosen to be zero or non-zero values. When Dᵢ=Dᵢ₊₁, Sᵢ=Sᵢ₊₁, for i>0, for the encoded symbol for every re-transmission chosen from the same SP. When at least one is changing from one re-transmission to another, SP with a different portion of the encoded symbols is transmitted for different re-transmissions. Note that Nᵢ=J₁ (log₂Mᵢ)Kᵢ, modulation order, number of Walsh codes and variable frame length can all be achieved by this method.
3. IR:

Initial transmission SP size No does not have to equal to EP size L. Nᵢ can be equal, smaller, or larger than L in the retransmissions. Dᵢ, and Sᵢ are not equal for i>0. At least one of them is non-zero such that a different SP is transmitted for each re-transmission. One requirement for full IR is that the symbols in each SP are different for up to a pre-defined number of transmissions. This requires careful design of Dᵢ and Sᵢ. One example is to let S₀=0, and Sᵢ₊₁=Sᵢ+1, and Dᵢ=0.

Sometimes, certain properties of when to transmit systematic and parity bits are desirable. For example, one may desire to transmit all systematic bits and part of the parity bits in the first transmission while only transmitting party bits in the re-transmissions. This can also be achieved by carefully designing Dᵢ and Sᵢ, including using multiply Dᵢ and Sᵢ in one (re)transmission.

In the cases where Dᵢ and/or Sᵢ will change for different re-transmissions, they can be either tied to certain counter type parameters, such as ARQ related counter, sequence number or frame counter, or passed through overhead control channels. Using counter type parameters, such as sequence number, avoids additional signaling overhead. This example can be extended to other rate matching algorithms, such as that used in 3GPP release 99 standard.

The present inventors found that a variety of IR or symbol combining schemes can be designed based on this method with different rate matching algorithms; and that this method provides low implementation complexity. Further, the “rate matching” algorithm can be made backward compatible.

At least one rate matching based IR/symbol combining scheme has been proposed by others subsequent to implementation of the present method by the present inventors, but have been limited since they have been tied to a specific standard. At least one rate matching based IR/symbol combining scheme has been tied to the 3GPP standard, for example. It is well know that symbol combining is a subset of IR. As a result, it is very easy to extend to IR.

In summary explanation of the above described method of incremental redundancy for link adaptation and code space management, a rate matching based IR/symbol combining scheme was described. The scheme can be used to design different IR using different rate matching algorithms. It has low implementation complexity and is easily made backward compatible.

In view of the above, it can be seen the present invention presents a significant advancement in the art of link adaptation and code space management. Further, this invention has been described in considerable detail in order to provide those skilled in the wireless data communication art with the information needed to apply the novel principles and to construct and use such specialized components as are required. In view of the foregoing descriptions, it should be apparent that the present invention represents a significant departure from the prior art in construction and operation. However, while particular embodiments of the present invention have been described herein in detail, it is to be understood that various alterations, modifications and substitutions can be made therein without departing in any way from the spirit and scope of the present invention, as defined in the claims which follow

1. A method of link adaptation and code space management comprising the steps of:
encoding original transmission bits into initial turbo encoded symbols;
storing the initial turbo encoded symbols;
interleaving and transmitting the initial turbo encoded symbols;
determining the number of Walsh codes available for a desired user and a modulation and coding scheme (MCS) level according to carrier to interference (C/I) feedback values from a desired mobile station;
determining rate matching factors corresponding to the number of available Walsh codes and the MCS level;
selectively puncturing or repeating the stored turbo encoded symbols based on the rate matching factors; and
re-transmitting the turbo encoded symbols subsequent to selectively puncturing or repeating the turbo encoded symbols.

2. The method according to claim 1, further comprising the steps of:
receiving the transmitted initial turbo encoded symbols and the re-transmitted turbo encoded symbols subsequent to selectively puncturing or repeating the turbo encoded symbols;
re-deriving the rate matching factors in response to the number of code channels and MCS level of current re-transmissions and the initial transmission;
selectively de-puncturing or de-repeating the received turbo encoded symbols based on the re-derived rate matching factors; and
coded symbol combining the selectively de-punctured or de-repeated turbo encoded symbols.

3. The method according to claim 2, wherein the step of coded symbol combining comprises full or partial symbol combing.

4. The method according to claim 2, wherein the step of coded symbol combining comprises Chase combining.

5. The method according to claim 2, wherein the step of coded symbol combining comprises Incremental Redundancy combining.

6. The method according to claim 1, wherein the step of storing the initial turbo encoded symbols comprises storing the initial turbo encoded symbols in a hybrid automatic re-transmission request (H-ARQ) memory.

7. The method of link adaptation and code space management according to claim 1, wherein the step of encoding original transmission bits into initial turbo encoded symbols comprises selectively turbo puncturing or avoiding puncturing of the original transmission bits to generate an encoded packet (EP) having the lowest code rate required by a desired incremental redundancy (IR).

8. The method according to claim 7, further comprising the step of determining the radio frame length according to a resource management algorithm.

9. The method according to claim 8, wherein the step of determining rate matching factors corresponding to the number of available Walsh codes and the MCS level further comprises determining the rate matching factors corresponding to the radio frame length.

10. The method according to claim 9, wherein the steps of interleaving and transmitting the initial turbo encoded symbols comprise:
generating a sub-packet (SP) from the EP based on the rate matching factors for this initial transmission; and
transmitting the SP.

11. The method according to claim 10, wherein the steps of selectively puncturing or repeating the stored turbo encoded symbols based on the rate matching factors and re-transmitting the turbo encoded symbols subsequent to selectively puncturing or repeating the turbo encoded symbols are replaced by the steps of determining a new set of rate matching factors according the MCS, number of Walsh codes, and radio frame length in response to an unsuccessful SP decoding signal via an acknowledge channel from a receiver; determining a new SP based on the new set or rate matching factors; and re-transmitting the new SP.

12. The method according to claim 11, further comprising the steps of:
receiving the transmitted initial SP and the re-transmitted new SP;
re-deriving the rate matching factors in response to the number of code channels, MCS level of current re-transmissions and the initial transmission, and parameters known to both transmission and receiving sides, wherein the parameters are selected from the group consisting of radio frame index, and scrambling code;
selectively de-puncturing or de-repeating the received sub-packets based on the re-derived rate matching factors; and
coded symbol combining the selectively de-punctured or de-repeated sub-packets, wherein the coded symbol combining is selected from the group consisting of IR combining, full symbol combining, and partial symbol combining.

13. A method of link adaptation and code space management comprising the steps of:
selectively turbo puncturing or avoiding puncturing of original transmission bits to generate an encoded packet (EP) having the lowest code rate required by a desired incremental redundancy (IR);
storing the EP in a hybrid automatic re-transmission request (H-ARQ) memory;
determining the number of Walsh codes available for a desired user, a modulation and coding scheme (MCS) level according to carrier to interference (C/I) feedback values from a desired mobile station, and the radio frame length according to a resource management algorithm;
determining rate matching factors corresponding to the number of available Walsh codes, the MCS level, and the radio frame length;
generating a sub-packet (SP) from the EP based on the rate matching factors; and
transmitting the SP.

14. The method according to claim 13 further comprising the steps of:
determining a new set of rate matching factors according the MCS, number of Walsh codes, and radio frame length in response to an unsuccessful SP decoding signal via an acknowledge channel from a receiver;
determining a new SP based on the new set or rate matching factors; and
re-transmitting the new SP.

15. The method according to claim 14 further comprising the steps of:
receiving the transmitted initial SP and the re-transmitted new SP;
re-deriving the rate matching factors in response to the number of code channels, MCS level of current re-transmissions and the initial transmission, and parameters known to both transmission and receiving sides, wherein the parameters are selected from the group consisting of radio frame index, and scrambling code;
selectively de-puncturing or de-repeating the received sub-packets based on the re-derived rate matching factors; and
coded symbol combining the selectively de-punctured or de-repeated sub-packets, wherein the coded symbol combining is selected from the group consisting of IR combining, full symbol combining, and partial symbol combining.

16. A link adaptation and code space management system comprising:
a transmission system comprising:
a channel encoder;
a hybrid automatic re-transmission request (H-ARQ) memory operational to store symbols generated via the channel encoder;
a rate matching stage operational to generate rate matching parameters corresponding to the number of available Walsh codes, modulation and code scheme (MCS) level according to carrier to interference feedback values from a mobile receiver, and radio frame length according to a resource management algorithm; and
a receiving system comprising:
a rate matching stage operational to re-generate the rate matching parameters;
a coded symbol combiner stage operational to implement at least one coded symbol combining of the type selected from the group consisting of incremental redundancy combining, full symbol combining, and partial symbol combining; and
a channel decoder operational to decode the coded symbols generated via the coded symbol combiner stage.

17. The link adaptation and code space management system according to claim 16, further comprising:
a transmission block interleaver operational to selectively interleave transmitted symbols;
a transmission modulator operational to modulate the transmitted symbols;
a receive demodulator operational to demodulate received symbols; and
a receive block interleaver operational to selectively interleave the demodulated symbols.

18. The link adaptation and code space management system according to claim 16, wherein the channel encoder comprises a turbo encoder.

19. The link adaptation and code space management system according to claim 18, wherein the channel decoder comprises a turbo decoder.

20. The link adaptation and code space management system according to claim 16, wherein the receive rate matching stage is operational to re-generate the rate matching parameters based on the number of available Walsh codes, MCS level, and parameters known to both transmission and receiving sides selected from the group consisting of radio frame index, and scrambling code.
